(19) United States
(12) Patent Application Publication
(10) Pub. No.: US 2024/0128724 A1
(43) Pub. Date: Apr. 18, 2024

(54) OPTICAL SEMICONDUCTOR DEVICE AND METHOD FOR PRODUCING SAME

(71) Applicant: Mitsubishi Electric Corporation, Tokyo (JP)

(72) Inventors: Kazuyuki ONOE, Tokyo (JP); Tsutomu YAMAGUCHI, Tokyo (JP); Yohei HOKAMA, Tokyo (JP)

(73) Assignee: Mitsubishi Electric Corporation, Tokyo (JP)

(21) Appl. No.: 18/546,692

(22) PCT Filed: Mar. 5, 2021
(86) PCT No.: PCT/JP2021/008601

§ 371 Date: Aug. 16, 2023

(51) Int. Cl. H01S 5/227; H01S 5/042; H01S 5/22

(52) U.S. Cl. CPC H01S 5/2275; H01S 5/04256; H01S 5/2205

(57) ABSTRACT

An optical semiconductor device according to the present disclosure includes: a first-conductivity-type semiconductor substrate having a projecting portion; second-conductivity-type intermediate layers formed on both sides of the projecting portion above the semiconductor substrate; a stripe-shaped mesa structure formed of a first-conductivity-type first cladding layer, an active layer, and a second-conductivity-type second cladding layer, which are laminated above a surface including a top of the projecting portion so as to be centered at the projecting portion; buried layers formed on both sides of the mesa structure, to block current; and a second-conductivity-type contact layer formed at surfaces of the mesa structure and the buried layers.

### TECHNICAL FIELD

The present disclosure relates to an optical semiconductor device and a method for producing the same.

### BACKGROUND ART

In recent years, a data communication volume in a mobile communication system has been rapidly increasing, and the communication volume is expected to be enormous as a 5th-generation mobile communication system (5G) is introduced and spreads after the introduction. In order to process such an enormous data communication volume at high speed, high-speed operation of an optical communication module used in a communication device is essential. In order to achieve the high-speed operation, an optical semiconductor device such as a semiconductor laser which is a light source is also required to have higher performance.

As a semiconductor laser for optical communication, for example, FIG. 3 in Patent Document 1 discloses an element structure in which a mesa structure is buried with high-resistance semiconductor layers. In this element structure, thin p-type semiconductor layers are formed from side surfaces of the mesa structure to flat portions other than the mesa structure of a semiconductor substrate, and then the high-resistance semiconductor layers are formed to bury the mesa structure. Thus, providing the thin p-type semiconductor layers can suppress leak current. In addition, if the thickness of the p-type semiconductor layer is small enough, it is possible to reduce an element capacitance inevitably generated when the p-type semiconductor layer is formed.

Thus, the semiconductor laser disclosed in Patent Document 1 achieves high-performance operation in which the element capacitance can be reduced and the leak current can be suppressed, as desired for a light source of an optical communication module.

### CITATION LIST

### Patent Document

Patent Document 1: Japanese Laid-Open Patent Publication No. 2011-249767

### SUMMARY OF THE INVENTION

### Problem to be Solved by the Invention

However, in the semiconductor laser disclosed in Patent Document 1, at a first buried layer which is the p-type semiconductor layer covering the mesa structure and the flat portion, a part having a smaller layer thickness than other parts might be produced due to a transition plane formed at the time of epitaxial growth. Thus, the first buried layer becomes discontinuous, and this can lead to a problem such as increase in the leak current or increase in the element capacitance.

The present disclosure has been made to solve the above problem, and an object of the present disclosure is to provide an optical semiconductor device that operates with high efficiency and at high speed while enabling reduction in leak current and an element capacitance, and a method for producing the same.

### Means to Solve the Problem

An optical semiconductor device according to the present disclosure includes: a first-conductivity-type semiconductor substrate having a projecting portion; second-conductivity-type intermediate layers formed on both sides of the projecting portion above the semiconductor substrate; a stripe-shaped mesa structure formed of a first-conductivity-type first cladding layer, an active layer, and a second-conductivity-type second cladding layer, which are laminated above a surface including a top of the projecting portion so as to be centered at the projecting portion; buried layers formed on both sides of the mesa structure, to block current; and a second-conductivity-type contact layer formed at surfaces of the mesa structure and the buried layers.

An optical semiconductor device production method according to the present disclosure includes the steps of: forming a projecting portion on a semiconductor substrate through etching; epitaxially growing intermediate layers on both sides of the projecting portion; sequentially epitaxially growing a first-conductivity-type first cladding layer, an active layer, and a second-conductivity-type second cladding layer at surfaces of the projecting portion and the intermediate layers; forming, through etching, a stripe-shaped mesa structure whose center coincides with a center of the projecting portion and which is formed of the first cladding layer, the active layer, and the second cladding layer; epitaxially growing buried layers for blocking current, on both sides of the mesa structure; and epitaxially growing a second-conductivity-type contact layer at surfaces of the mesa structure and the buried layers.

### Effect of the Invention

The optical semiconductor device according to the present disclosure includes the first-conductivity-type semiconductor substrate having the projecting portion, and the intermediate layers formed on both sides of the projecting portion, whereby leak current and an element capacitance can be reduced, thus providing an effect of obtaining an optical semiconductor device that operates with high efficiency and at high speed.

In the optical semiconductor device production method according to the present disclosure, the stripe-shaped projecting portion is formed on the first-conductivity-type semiconductor substrate through etching and the second-conductivity-type intermediate layers are formed on both sides of the projecting portion through selective growth by epitaxial growth, thus providing an effect that an optical semiconductor device that operates with high efficiency and at high speed can be easily produced.

### BRIEF DESCRIPTION OF THE DRAWINGS

FIG. 1 is a sectional view showing the structure of an optical semiconductor device according to embodiment 1.

FIG. 2A is a sectional view showing the structure of an optical semiconductor device in a comparative example, and FIG. 2B shows an equivalent circuit of the optical semiconductor device in the comparative example.

FIG. 3 is a sectional view showing an optical semiconductor device production method according to embodiment 1.

FIG. 4 is a sectional view showing the optical semiconductor device production method according to embodiment 1.

FIG. 5 is a sectional view showing the optical semiconductor device production method according to embodiment 1.

FIG. 6 is a sectional view showing the optical semiconductor device production method according to embodiment 1.

FIG. 7 is a sectional view showing the optical semiconductor device production method according to embodiment 1.

FIG. 8 is a sectional view showing the optical semiconductor device production method according to embodiment 1.

FIG. 9 is a sectional view showing the optical semiconductor device production method according to embodiment 1.

FIG. 10 is a sectional view showing the optical semiconductor device production method according to embodiment 1.

FIG. 11 is a sectional view showing the optical semiconductor device production method according to embodiment 1.

FIG. 12 is a sectional view showing the optical semiconductor device production method according to embodiment 1.

FIG. 13 is a sectional view showing the optical semiconductor device production method according to embodiment 1.

FIG. 14 is a sectional view showing the optical semiconductor device production method according to embodiment 1.

FIG. 15 is a sectional view showing the optical semiconductor device production method according to embodiment 1.

FIG. 16 is a sectional view showing the structure of an optical semiconductor device according to embodiment 2.

FIG. 17 is a sectional view showing an optical semiconductor device production method according to embodiment 2.

FIG. 18 is a sectional view showing the optical semiconductor device production method according to embodiment 2.

FIG. 19 is a sectional view showing the structure of an optical semiconductor device according to embodiment 3.

FIG. 20 is a sectional view showing the structure of an optical semiconductor device according to embodiment 4.

FIG. 21 is a sectional view showing the structure of an optical semiconductor device according to embodiment 5.

FIG. 22 is a sectional view showing a major part of the structure of an optical semiconductor device according to embodiment 6.

### DESCRIPTION OF EMBODIMENTS

### Embodiment 1

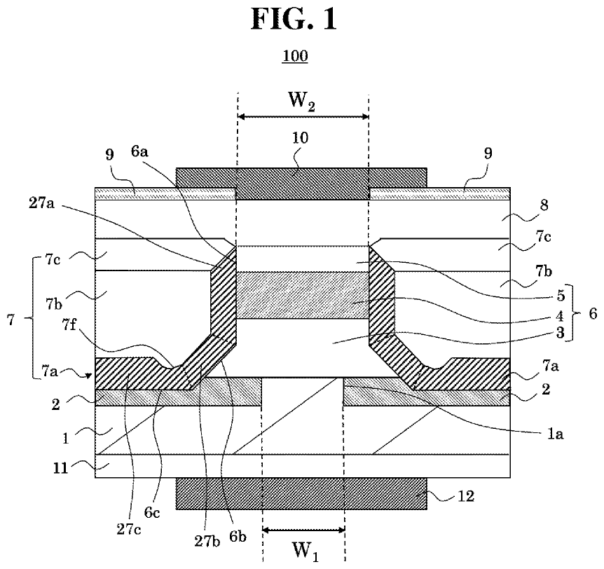

FIG. 1 is a sectional view showing the structure of an optical semiconductor device 100 according to embodiment 1.

The optical semiconductor device 100 is, for example, a semiconductor laser, and an example thereof is a buried-structure semiconductor laser. The buried-structure semiconductor laser may have a buried heterostructure.

The optical semiconductor device 100 includes: a first-conductivity-type semiconductor substrate 1 having a projecting portion 1a; second-conductivity-type intermediate layers 2 formed on both sides of the projecting portion 1a above the semiconductor substrate 1; a stripe-shaped mesa structure 6 formed of a first-conductivity-type first cladding layer 3, an active layer 4, and a second-conductivity-type second cladding layer 5, which are laminated above a surface including a top of the projecting portion 1a so as to be centered at the projecting portion 1a; buried layers 7 formed on both sides of the mesa structure 6 and each composed of three layers that are a second-conductivity-type first buried layer 7a, a first-conductivity-type second buried layer 7b, and a second-conductivity-type third buried layer 7c; a second-conductivity-type contact layer 8 formed at surfaces of the mesa structure 6 and the third buried layers 7c; a surface protection film 9 formed above the second-conductivity-type contact layer 8 and having an opening; a first electrode 10 contacting with a surface of the second-conductivity-type contact layer 8 via the opening of the surface protection film 9; and a second electrode 11 and a metal plating film 12 formed on the back surface side of the semiconductor substrate 1.

The first conductivity type and the second conductivity type described above may be p type and n type, respectively, or may be n type and p type, respectively.

The first-conductivity-type semiconductor substrate 1 is, for example, an n-type indium phosphide (InP) substrate. The second-conductivity-type intermediate layer is made from p-type InP, for example. The first-conductivity-type first cladding layer 3 is made from n-type InP, for example. The second-conductivity-type second cladding layer 5 is made from p-type InP, for example. The second-conductivity-type contact layer 8 is made from p-type InP, for example.

The active layer 4 has a strained multi-quantum well structure. This structure can achieve higher output and lower strain of the optical semiconductor device 100.

The first buried layer 7a composing the buried layer 7 is made from p-type InP, for example, and is doped with zinc (Zn) so that the conductivity type becomes p type. The second buried layer 7b is made from n-type InP, for example, and the third buried layer 7c is made from p-type InP, for example.

As shown in FIG. 1, the p-type first buried layer 7a is formed of three parts, i.e., a side surface portion 27a along a side surface 6a of the mesa structure 6, a flat portion 27c formed at a surface of the second-conductivity-type intermediate layer 2 along a bottom portion 6c of the mesa structure 6, and a slope portion 27b connecting the side surface portion 27a and the flat portion 27c along a slope surface 6b formed between the side surface 6a and the bottom portion 6c of the mesa structure 6. The side surface portion 27a extends to the same height as an upper surface of the second cladding layer 5 and has a tapered shape at the upper end.

Hereinafter, the width of the projecting portion 1a in the stripe width direction is referred to as a width W₁. In addition, the width between the side surfaces 6a on both sides of the mesa structure 6 is referred to as a mesa width W₂, and the width between ends of the bottom portions 6c from which the bottom portions 6c extend on both sides of the mesa structure 6 is also referred to as a bottom portion width of the mesa structure 6.

The center in the stripe width direction of the mesa structure 6 and the center in the stripe width direction of the projecting portion 1a coincide with each other or substantially coincide with each other. The sectional shape of the projecting portion 1a is a rectangular shape. The width W₁ of the projecting portion 1a is set in advance so as to be smaller than the mesa width W₂ of the mesa structure 6.

It is desirable that the layer thickness of the flat portion 27c of the p-type first buried layer 7a is not less than two times the layer thickness of the side surface portion 27a. The reason is as follows.

Of leak current flowing in the p-type first buried layer 7a with respect to injected current of the entire optical semiconductor device 100, in particular, the ratio of leak current flowing in the side surface portion 27a covering the side surface of the active layer 4 is proportional to the sectional area of the p-type first buried layer 7a. Therefore, of the p-type first buried layer 7a, if the side surface portion 27a covering the side surface of the active layer 4 is thinned, leak current can be reduced.

However, if the p-type first buried layer 7a is excessively thinned, leak current might increase on the contrary. Therefore, of the p-type first buried layer 7a, in particular, controlling the side surface portion 27a covering the side surface of the active layer 4 to have an optimum layer thickness is very important for high efficiency and stable operation of the optical semiconductor device 100.

In the optical semiconductor device 100 according to embodiment 1, the layer thickness of the flat portion 27c is set to be not less than two times the layer thickness of the side surface portion 27a. If the layer thickness of the flat portion 27c is less than two times the layer thickness of the side surface portion 27a, when the side surface portion 27a is excessively thinned, the layer thickness of the flat portion 27c is also thinned at the same time, so that particularly a problem of increasing leak current becomes significant due to a part having a relatively small layer thickness because of formation of a transition plane 7f described later.

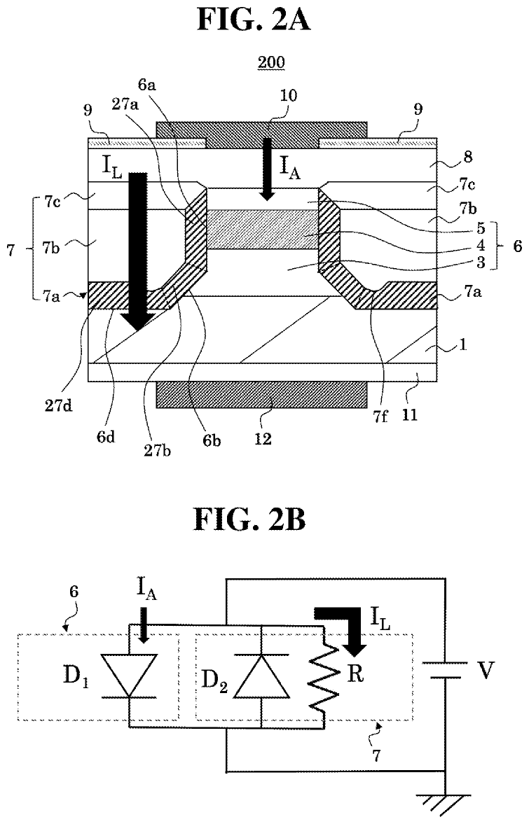

Before describing operation of the optical semiconductor device 100 according to embodiment 1, first, an optical semiconductor device 200 which is a comparative example will be described. FIG. 2A is a sectional view showing the structure of the optical semiconductor device 200 in the comparative example, and FIG. 2B shows an equivalent circuit of the mesa structure 6 and the buried layer 7 in the optical semiconductor device 200. In FIG. 2B, the first conductivity type is n type, and the second conductivity type is p type. The optical semiconductor device 200 in the comparative example is not provided with the second-conductivity-type intermediate layer 2 as in the optical semiconductor device 100 according to embodiment 1.

The mesa structure 6 part including the active layer 4 forms, in terms of an equivalent circuit, a diode D₁ as shown in the equivalent circuit diagram in FIG. 2B. That is, a p-n junction diode D₁ is formed by the n-type first cladding layer 3, the active layer 4, and the p-type second cladding layer 5.

On the other hand, in the buried layer 7 part, a p-n junction diode D₂ is formed by the p-type first buried layer 7a and the n-type second buried layer 7b, and in addition, the buried layer 7 itself is represented as a resistor R.

In the equivalent circuit diagram shown in FIG. 2B, the anode of the diode D₁ and the cathode of the diode D₂ are connected, and the cathode of the diode D₁ and the anode of the diode D₂ are connected. The resistor R of the buried layer 7 is connected in parallel to the diode D₁ and the diode D₂.

For causing the optical semiconductor device 200 to emit a laser beam, the positive side of a DC power supply V and the first electrode 10 which is a front-surface electrode are electrically connected, the negative side of the DC power supply V and the second electrode 11 which is a back-surface electrode are electrically connected via the metal plating film 12, and voltage is applied by the DC power supply V. With voltage applied by the DC power supply V, voltage is applied in the forward bias direction to the diode D₁ which equivalently represents the mesa structure 6. Thus, current I_{A} injected from the first electrode 10 of the optical semiconductor device 200 flows through the p-type contact layer 8 to the mesa structure 6, so that a laser beam is produced in the active layer 4.

On the other hand, in the diode D₂ and the resistor R which equivalently represent the buried layer 7, the above voltage applied by the DC power supply V is applied in the reverse bias direction. Thus, current does not flow in the diode D₂ part of the buried layer 7, and flows only in the resistor R part as leak current I_{L}.

The resistance value of the resistor R is originally high, and therefore, owing to the high resistance, the leak current I_{L} is at a negligible level. That is, the buried layer 7 serves as a current block layer. As a result, current injected in the optical semiconductor device 200 flows being concentrated in the mesa structure 6 owing to a current confinement effect by the buried layers 7 provided on both sides of the mesa structure 6 and serving as current block layers. Thus, the optical semiconductor device 200 is originally able to emit a laser beam with high efficiency with respect to injected current owing to the current confinement effect by the buried layers 7.

However, in the optical semiconductor device 200 in the comparative example, when the p-type first buried layers 7a which are first layers formed as the buried layers 7 are formed on both sides of the mesa structure 6 through epitaxial growth, the layer thickness is not uniform over the entire area and thus parts having relatively small layer thicknesses, i.e., transition planes 7f, are likely to be formed.

As is found from FIG. 2A, the p-type first buried layer 7a of the optical semiconductor device 200 in the comparative example is formed of three parts, i.e., the side surface portion 27a along the side surface 6a of the mesa structure 6, a flat portion 27d along a bottom portion 6d of the mesa structure 6, and the slope portion 27b along the slope surface 6b connecting the side surface portion 27a and the flat portion 27d. The transition plane 7f of the p-type first buried layer 7a is likely to be formed at a flat portion 27d part close to the slope portion 27b.

Hereinafter, the mechanism of formation of the transition plane 7f and a problem caused by the transition plane 7f will be described, using an optical semiconductor device made from an InP material as an example.

The plane orientation of the side surface 6a of the mesa structure 6 is a (110) plane. The plane orientation of the upper surface of the bottom portion 6d of the mesa structure 6 is a (001) plane.

In epitaxial growth of the buried layer 7, when the p-type InP first buried layer 7a which is the first layer is formed, epitaxial growth on a (001) plane corresponding to the bottom portion 6d of the mesa structure 6 and epitaxial growth of p-type InP on a (110) plane corresponding to the side surface 6a of the mesa structure 6, progress simultaneously.

In epitaxial growth of the p-type InP first buried layer 7a, a phenomenon called migration occurs, so that epitaxial growth on a (111)B plane also occurs. Both of the (111)B plane and the (001) plane are plane orientations in which the p-type InP first buried layer 7a is readily epitaxially grown. A part where such planes exhibiting high growth speeds cross each other forms the transition plane 7f.

At the transition plane 7f, crystal growth materials, i.e., In and P, are taken to the (111)B plane side and the (001) plane side, so that the p-type InP first buried layer 7a is less grown. As a result, the layer thickness of the p-type InP first buried layer 7a at the transition plane 7f becomes relatively small as compared to other parts.

When the influence of the transition plane 7f is great, the p-type InP first buried layer 7a might become discontinuous at a transition plane 7f part, and this causes a problem of connecting the n-type InP semiconductor substrate 1 and the n-type InP second buried layer 7b.

In order to reduce the influence of the transition plane 7f, it is conceivable to increase the layer thickness of the p-type InP first buried layer 7a. However, if the layer thickness of the p-type InP first buried layer 7a is merely increased, there might be a problem that the thickness of the n-type InP second buried layer 7b laminated next to the p-type InP first buried layer 7a cannot be ensured. In a case where the thickness of the n-type InP second buried layer 7b cannot be ensured, the element capacitance increases, thus causing a problem of obstructing speed increase of the optical semiconductor device.

Thus, the mechanism of formation of the transition plane 7f and the problem caused by the transition plane 7f are as described above.

As described above, at the transition plane 7f of the p-type InP first buried layer 7a, the effective resistance is reduced and this might cause a problem that a component of leak current I_{L} passing through the small-layer-thickness part increases to a level not negligible. In the equivalent circuit, the above increase of the leak current results in reduction in the resistor R shown in FIG. 2B, and this causes reduction in efficiency in laser operation of the optical semiconductor device 200. Further, increase in the leak current I_{L} also causes increase in the element capacitance.

As a method for preventing increase in leak current due to the transition plane 7f of the p-type InP first buried layer 7a, a method of increasing the layer thickness of the p-type InP first buried layer 7a may be conceivable as described above, but in order that the buried layer 7 having a three-layer structure stably exhibits a function as a current block layer, in the p-type InP first buried layer 7a, the layer thickness of the side surface portion 27a formed at the side surface 6a of the mesa structure 6, in particular, the side surface of the active layer 4, and the layer thickness of the flat portion 27d on the bottom portion 6d side of the mesa structure 6, need to be formed stably and in a well-balanced manner. For the above reason, there is a problem that the layer thickness of the p-type InP first buried layer 7a cannot be merely increased.

In the optical semiconductor device 100 according to embodiment 1, the second-conductivity-type intermediate layer 2 is provided in order to solve the problem that the leak current and the element capacitance increase in the optical semiconductor device 200 in the comparative example. Hereinafter, the function of the second-conductivity-type intermediate layer 2 will be described.

As described in detail in the method for producing the optical semiconductor device 100 according to embodiment 1 later, the second-conductivity-type intermediate layers 2 are formed separately from the second-conductivity-type first buried layers 7a which can cause increase in the leak current I_{L}, and therefore, even if parts having a relatively small layer thickness are produced due to formation of the transition planes 7f when the second-conductivity-type first buried layers 7a are formed on both sides of the mesa structure 6, the thicknesses of second-conductivity-type layers are increased as a whole with the second-conductivity-type intermediate layers 2 provided. Thus, the problem due to non-uniformity of the layer thickness of the first buried layer 7a, which is caused in the comparative example, is solved. Hereinafter, with reference to the equivalent circuit shown in FIG. 2B, description will be given in more detail.

In the optical semiconductor device 100 according to embodiment 1, the second-conductivity-type intermediate layer 2 having the same conductivity type as the second-conductivity-type first buried layer 7a is provided on the first-conductivity-type semiconductor substrate 1 side with respect to the second-conductivity-type first buried layer 7a.

Therefore, when the equivalent circuit shown in FIG. 2B is applied to the optical semiconductor device 100 according to embodiment 1, the diode D₂ representing the buried layer 7 is formed to be a p-n junction diode D₂ by the n-type second buried layer 7b and a p-type layer formed of the p-type intermediate layer 2 and the p-type first buried layer 7a, in the optical semiconductor device 100 according to embodiment 1.

In other words, it can be said that the second-conductivity-type first buried layer 7a is reinforced by the intermediate layer 2 having the same second conductivity type. Therefore, even if a part having a relatively small layer thickness, i.e., the transition plane 7f, is present in the second-conductivity-type first buried layer 7a, the second-conductivity-type layer is effectively thickened by the layer thickness of the second-conductivity-type intermediate layer 2 provided on the semiconductor substrate 1 side, thus providing an effect of preventing production of a part having a relatively small layer thickness which can cause the leak current I_{L}. In addition, since the leak current I_{L} flowing in the buried layer 7 is reduced, the element capacitance can also be reduced.

In the optical semiconductor device 100 according to embodiment 1, the width W₁ in the stripe width direction of the projecting portion 1a whose sectional shape along the stripe width direction is a rectangular shape is set to be smaller than the mesa width W₂ of the mesa structure 6, as shown in the sectional view in FIG. 1. That is, the width W₁ between the ends of the second-conductivity-type intermediate layers 2 that contact with the projecting portion 1a in the stripe width direction is smaller than the mesa width W₂ of the mesa structure 6.

In terms of current confinement, it can be said that the opening width W₁ between the second-conductivity-type intermediate layers 2 for blocking flow of current is set to be smaller than the mesa width W₂ of the mesa structure 6. Thus, current flowing through the mesa structure 6 is subjected to further current confinement by the second-conductivity-type intermediate layers 2 having the opening width W₁.

That is, in the optical semiconductor device 100 according to embodiment 1, a current confinement effect by the buried layers 7 and a current confinement effect by the second-conductivity-type intermediate layers 2 are synergistically exerted, thus providing an effect of further improving efficiency of the optical semiconductor device 100.

In addition, with the second-conductivity-type intermediate layer 2 provided, the leak current I_{L} flowing in the buried layer 7 can be reduced, so that the element capacitance is also reduced, thus providing an effect of enabling high-speed operation of the optical semiconductor device 100 as well.

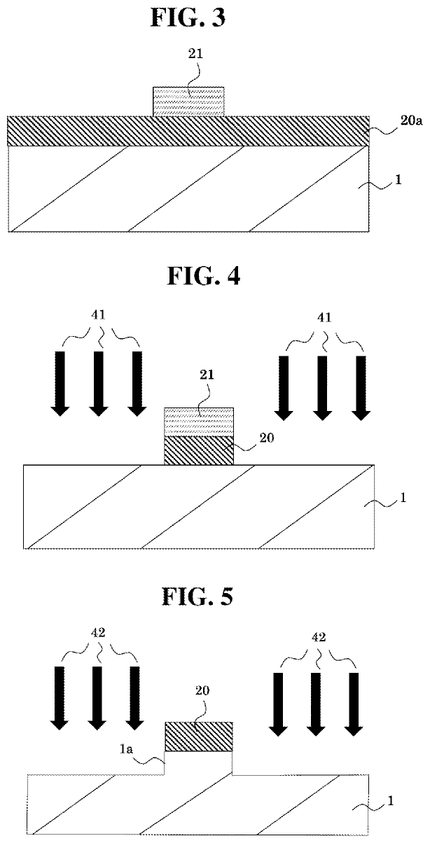

Next, the method for producing the optical semiconductor device 100 according to embodiment 1 will be described with reference to FIG. 3 to FIG. 15. In the following description, an InP-based crystal material is shown as a specific example of the material forming the optical semiconductor device 100. However, the crystal material forming the optical semiconductor device 100 according to embodiment 1 is not limited to an InP-based material. As long as the crystal material can form the optical semiconductor device, the optical semiconductor device production method described below can be applied in the same manner, by selecting, for example, a dry etching gas material or the like so as to be optimum for dry etching of the crystal material.

First, above the n-type InP semiconductor substrate 1, a SiO₂ film 20a to be a mask 20 in selective growth by epitaxial growth is formed. As a method for forming the SiO₂ film 20a, for example, plasma chemical vapor deposition (CVD) may be used.

With a photoresist applied on the SiO₂ film 20a, a stripe-shaped photoresist mask 21 as shown in FIG. 3 is formed using photolithography and etching. The photoresist mask 21 serves as an etching mask for forming the SiO₂ film 20a into a stripe-shaped mask 20.

Using the photoresist mask 21 as an etching mask, the SiO₂ film 20a is dry-etched to be worked into the stripe-shaped mask 20 formed of the SiO₂ film as shown in FIG. 4. As a dry etching method, for example, plasma dry etching may be used. An example of an etching gas 41 for dry etching is a fluorine-based gas such as SF₆/He gas.

After the dry etching, the photoresist mask 21 is removed. At the part where the SiO₂ film 20a is removed through dry etching, the n-type InP semiconductor substrate 1 is exposed.

Using the stripe-shaped mask 20 formed of the SiO₂ film as an etching mask, the n-type InP semiconductor substrate 1 is dry-etched. A specific example of an etching gas 42 for dry etching is a methane-based gas or a chlorine-based gas.

The depth to which the n-type InP semiconductor substrate 1 is dry-etched is, for example, 400 nm. FIG. 5 shows a cross-section after the dry etching.

Through the dry etching, the stripe-shaped projecting portion 1a is formed on the n-type InP semiconductor substrate 1. Here, the stripe-shaped projecting portion 1a refers to a projecting structure which is formed to extend in the direction along a waveguide, i.e., the mesa structure 6 described later, and whose cross-section along a direction perpendicular to the waveguide, i.e., along the stripe width direction, has a rectangular shape.

The height from the flat surface of the n-type InP semiconductor substrate 1 to the top of the projecting portion 1a is the same as the depth to which n-type InP has been removed through dry etching. That is, in the aforementioned example, the height is 400 nm.

Using the stripe-shaped mask 20 formed of the SiO₂ film as a selective growth mask, selective growth by epitaxial growth is performed to form the p-type InP intermediate layers 2 on both sides of the projecting portion 1a above the n-type InP semiconductor substrate 1. An example of the epitaxial growth is metal organic chemical vapor deposition (MOCVD).

In the selective growth, a crystal layer, i.e., an InP layer, is not formed above the stripe-shaped mask 20 formed of the SiO₂ film. That is, the p-type InP intermediate layers 2 are epitaxially grown above the flat surfaces of the n-type InP semiconductor substrate 1. Thus, as shown in the sectional view in FIG. 6, both sides of the projecting portion 1a are buried with the p-type InP intermediate layers 2.

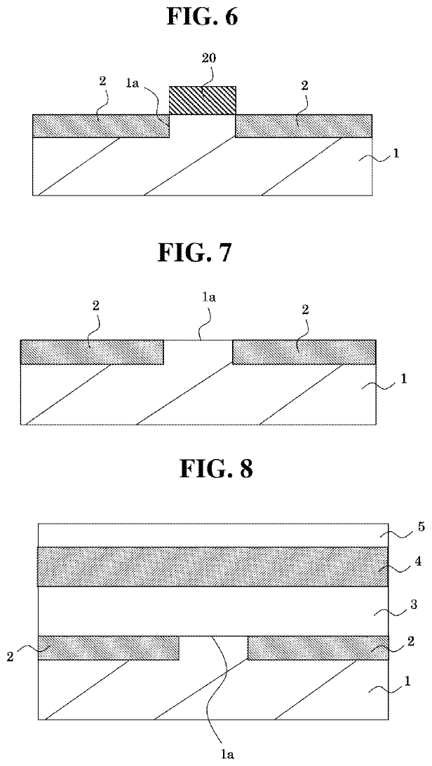

After the selective growth of the p-type InP intermediate layers 2, the stripe-shaped mask 20 formed of the SiO₂ film is removed through dry etching. FIG. 7 shows a sectional view after the mask 20 is removed. The surface of the projecting portion 1a and the surfaces of the p-type InP intermediate layers 2 are continuous so as to form one flat surface as a whole.

After the mask 20 is removed, by MOCVD, the n-type InP first cladding layer 3, the active layer 4, and the p-type InP second cladding layer 5 are sequentially epitaxially grown above the surface formed by the top of the projecting portion 1a and the surfaces of the p-type InP intermediate layers 2. FIG. 8 is a sectional view after the epitaxial growth.

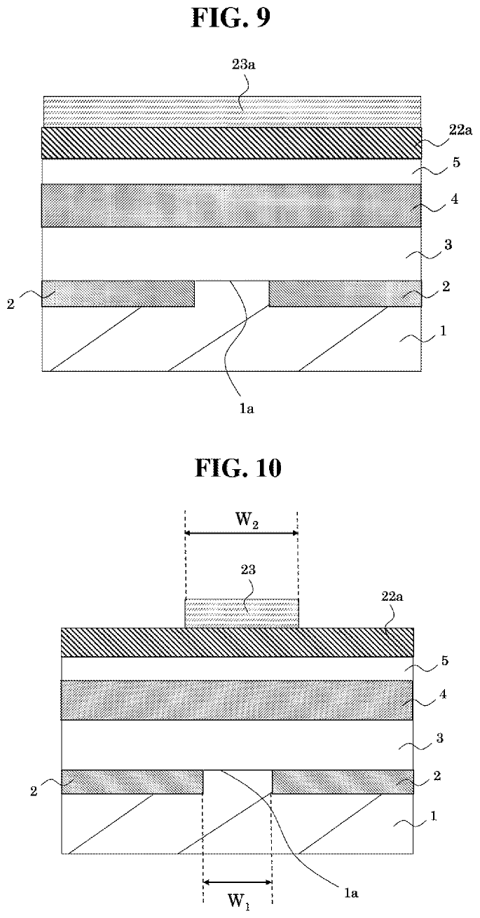

A SiO₂ film 22a is formed on the surface of the p-type InP second cladding layer 5. As a method for forming the SiO₂ film 22a, for example, plasma CVD may be used. A photoresist film 23a is applied on the SiO₂ film 22a. FIG. 9 is a sectional view showing the state in which the SiO₂ film 22a and the photoresist film 23a are formed.

Using photolithography and etching, a stripe-shaped photoresist mask 23 as shown in FIG. 10 is formed. The photoresist mask 23 serves as an etching mask for forming the SiO₂ film 22a into a stripe-shaped mask 22.

The position of the photoresist mask 23 is adjusted so that the center in the stripe width direction of the photoresist mask 23 and the center in the stripe width direction of the projecting portion 1a coincide with each other or substantially coincide with each other. In addition, the width W₂ of the projecting portion 1a in the stripe width direction is set to be smaller than the stripe width W₂ of the photoresist mask 23.

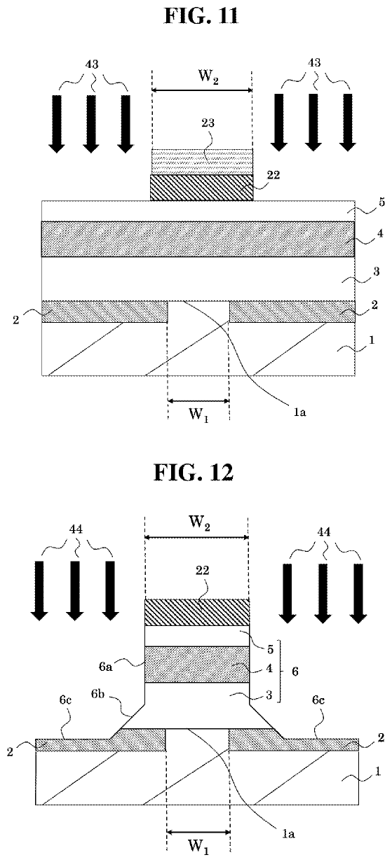

Using the stripe-shaped photoresist mask 23 as an etching mask, the SiO₂ film 22a is dry-etched to be worked into the stripe-shaped mask 22 formed of the SiO₂ film as shown in FIG. 11. An example of an etching gas 43 for dry etching is a fluorine-based gas. At the part where the SiO₂ film 22a is removed through dry etching, the p-type InP second cladding layer 5 is exposed. After the dry etching, the photoresist mask 23 is removed.

Using the stripe-shaped mask 22 formed of the SiO₂ film as an etching mask, the p-type InP second cladding layer 5, the active layer 4, and the n-type InP first cladding layer 3 are dry-etched, and further, parts of the p-type InP intermediate layers 2 are dry-etched, thereby forming the mesa structure 6 as shown in the sectional view in FIG. 12. A specific example of an etching gas 44 for dry etching is a methane-based gas or a chlorine-based gas.

In the above dry etching for the mesa structure 6, the slope surfaces 6b are formed on the bottom portion sides of the side surfaces 6a of the mesa structure 6. Also, in buried growth of the buried layers 7 by epitaxial growth described later, when the temperature is increased before the growth, formation of the slope surfaces 6b is promoted through migration.

The depth to which the p-type InP intermediate layers 2 are dry-etched is, for example, 200 nm. Since the layer thickness of the p-type InP intermediate layer 2 before dry etching is 400 nm, the halves of the p-type InP intermediate layers 2 are removed in the layer thickness direction through the dry etching.

The center in the stripe width direction of the mesa structure 6 and the center in the stripe width direction of the projecting portion 1a coincide with each other or substantially coincide with each other. The mesa structure 6 is formed by dry-etching, into a stripe shape, the n-type InP first cladding layer 3, the active layer 4, and the p-type InP second cladding layer 5 laminated above the surface including the top of the projecting portion 1a.

The mesa width of the mesa structure 6 after dry etching is almost the same width W₂ as the stripe width of the photoresist mask 23. This is because, owing to the nature of dry etching, the width W₂ is kept also on the etching-target side when the crystal layer is dry-etched. As a result, the width W₁ of the projecting portion 1a in the stripe width direction becomes smaller than the mesa width W₂ of the mesa structure 6.

As shown in FIG. 12, the mesa structure 6 formed through dry etching has, on each of both sides of the mesa structure 6, three surfaces that are the side surface 6a along a direction perpendicular to the surface of the n-type InP semiconductor substrate 1, the surface of the p-type InP intermediate layer 2 exposed by dry etching, i.e., the bottom portion 6c of the mesa structure 6, and the slope surface 6b connecting the side surface 6a and the bottom portion 6c of the mesa structure 6.

After the mesa structure 6 is formed, using the stripe-shaped mask 22 formed of the SiO₂ film as a selective growth mask, buried growth is performed in regions on both sides of the mesa structure 6 having the above surfaces. As a crystal growth method for the buried growth, the aforementioned MOCVD is preferable. By MOCVD, first, the p-type InP first buried layers 7a which are the first layers of the buried layers 7 each formed of three layers are epitaxially grown.

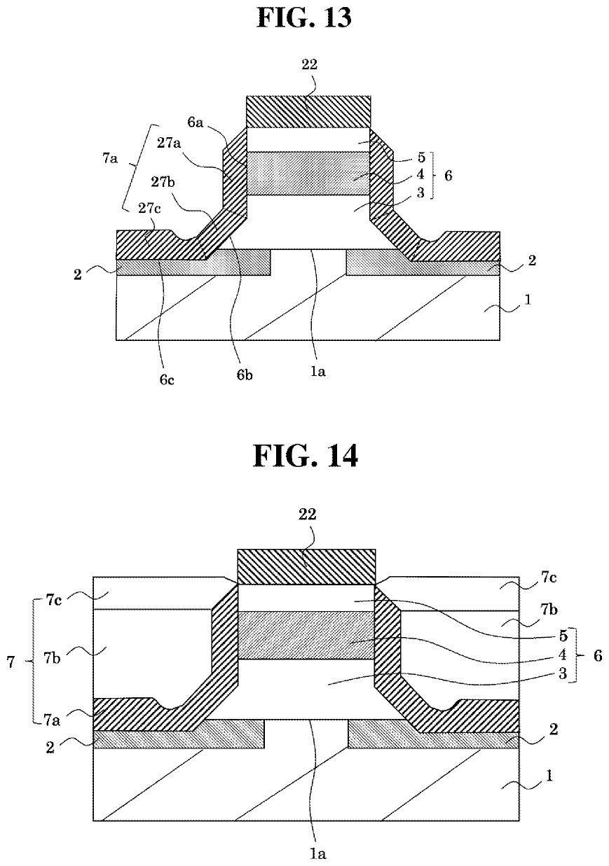

As shown in FIG. 13 which is a sectional view after the p-type InP first buried layers 7a are formed, the p-type InP first buried layers 7a are formed with the shape of the mesa structure 6 reflected and thus are each composed of three parts that are the side surface portion 27a along the side surface 6a of the mesa structure 6, the flat portion 27c along the surface of the p-type InP intermediate layer 2, i.e., the bottom portion 6c of the mesa structure 6, and the slope portion 27b connecting the side surface portion 27a and the flat portion 27c along the slope surface 6b.

Subsequent to the p-type InP first buried layers 7a, the n-type InP second buried layers 7b and the p-type InP third buried layers 7c are sequentially laminated through epitaxial growth. As shown in a sectional view in FIG. 14, through epitaxial growth of the buried layers 7 each formed of three layers sequentially laminated, both sides of the mesa structure 6 are buried with the buried layers 7, so that the surface of the mesa structure 6 and the surfaces of the buried layers 7 form an almost flat surface.

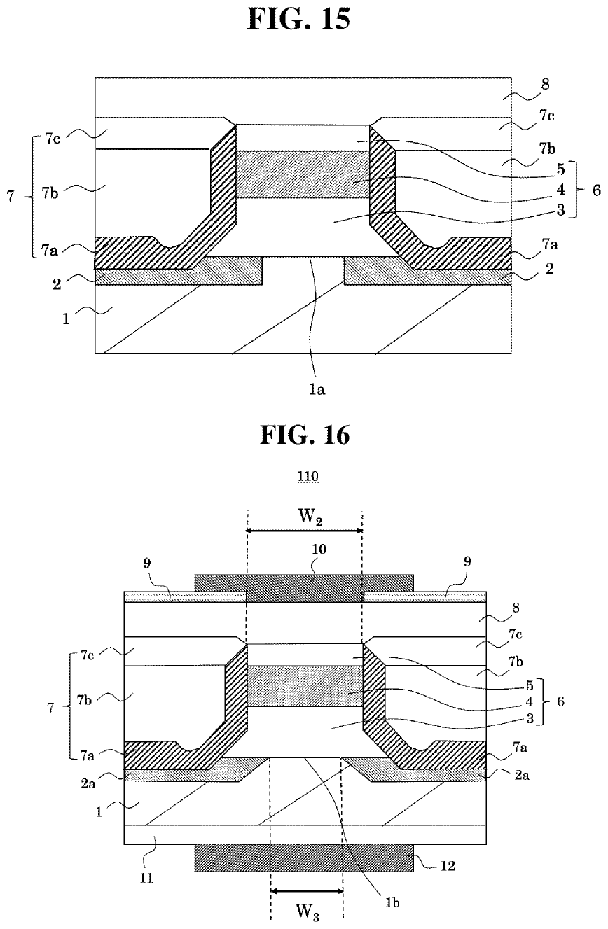

After epitaxial growth of the buried layers 7, the stripe-shaped mask 22 formed of the SiO₂ film is removed through dry etching. With the mask 22 removed, above the surfaces of the p-type InP second cladding layer 5 forming the surface of the mesa structure 6 and the p-type InP third buried layers 7c forming the surfaces of the buried layers 7, the p-type InP contact layer 8 is epitaxially grown by MOCVD. FIG. 15 is a sectional view after the p-type InP contact layer 8 is formed. The p-type InP contact layer 8 serves to allow current to efficiently flow inside the optical semiconductor device 100 from the first electrode 10.

After all the epitaxial growth, the surface protection film 9 having an opening is formed on the surface of the p-type InP contact layer 8, and further, the first electrode 10 is formed to be electrically connected by contacting with the p-type InP contact layer 8 via the opening of the surface protection film 9. The surface protection film 9 serves to reduce a parasitic capacitance and protect the semiconductor layers.

After working on the front surface side of the n-type InP semiconductor substrate 1 is finished, the second electrode 11 and the metal plating film 12 are formed on the back surface side of the n-type InP semiconductor substrate 1, whereby the optical semiconductor device 100 as shown in the sectional view in FIG. 1 is completed.

In the method for producing the optical semiconductor device 100 according to embodiment 1, using the mask 20 as an etching mask, the stripe-shaped projecting portion 1a is formed on the first-conductivity-type semiconductor substrate 1 through dry etching, and using the mask 20 as a selective growth mask, the second-conductivity-type intermediate layers 2 are formed on both sides of the projecting portion 1a through selective growth by epitaxial growth, thus providing an effect that the optical semiconductor device 100 that operates with high efficiency and at high speed can be easily produced.

As described above, the optical semiconductor device 100 according to embodiment 1 includes the first-conductivity-type semiconductor substrate 1 having the projecting portion 1a, and the intermediate layers 2 formed on both sides of the projecting portion 1a and having an opening width smaller than the mesa width, whereby the leak current and the element capacitance can be reduced, thus providing an effect of obtaining the optical semiconductor device that operates with high efficiency and at high speed.

### Embodiment 2

FIG. 16 shows a sectional view of an optical semiconductor device 110 according to embodiment 2. As a structural difference from the optical semiconductor device 100 according to embodiment 1, the optical semiconductor device 110 according to embodiment 2 is configured such that the sectional shape along the stripe width direction of a projecting portion 1b is not a rectangular shape but a trapezoidal shape.

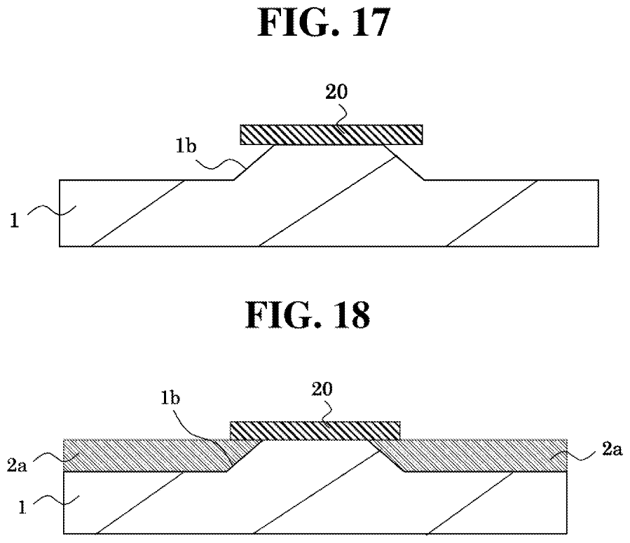

FIG. 17 and FIG. 18 show a characteristic process in the method for producing the optical semiconductor device 110 according to embodiment 2.

The process until the stripe-shaped mask 20 formed of the SiO₂ film is formed above the first-conductivity-type semiconductor substrate 1 as shown in FIG. 4 is the same as the method for producing the optical semiconductor device 100 according to embodiment 1.

Using the mask 20 as an etching mask, the first-conductivity-type semiconductor substrate 1 is wet-etched. Through the wet etching, working is performed so that side surfaces of the projecting portion 1b have a forward mesa shape as shown in a sectional view in FIG. 17. As a result of the wet etching, the sectional shape along the stripe width direction of the projecting portion 1b becomes a trapezoidal shape.

Using the mask 20 as a selective growth mask, second-conductivity-type intermediate layers 2a are formed on both sides of the projecting portion 1b through selective growth by epitaxial growth. An example of the epitaxial growth is MOCVD. A specific example of the second-conductivity-type intermediate layer 2a is a p-type InP intermediate layer 2a.

In the selective growth, while a crystal layer is not formed above the mask 20, epitaxial growth occurs also under the mask 20. Therefore, as shown in a sectional view in FIG. 18, both sides of the projecting portion 1b whose cross-section has a trapezoidal shape are buried with the second-conductivity-type intermediate layers 2a.

After the selective growth of the second-conductivity-type intermediate layers 2a, the mask 20 is removed through dry etching. The production process after the mask 20 is removed is the same as in the method for producing the optical semiconductor device 100 according to embodiment 1 as shown in FIG. 8 to FIG. 15.

In the optical semiconductor device 110 according to embodiment 2, the sectional shape of the projecting portion 1b is made into a trapezoidal shape, whereby, in a case where a width W₃ of the top of the projecting portion 1b in the stripe width direction is the same as the width W₁ of the rectangular-shaped projecting portion 1a of the optical semiconductor device 100 according to embodiment 1, in the optical semiconductor device 110 according to embodiment 2, since the projecting portion 1b spreads in a trapezoidal shape from its top located on the bottom portion side of the mesa structure 6 toward the back surface side of the semiconductor substrate 1, current flowing in the mesa structure 6 leads to the second electrode 11 through a region having a wider sectional area. That is, the sectional area of the region where current flows increases, thus providing an effect that the effective element resistance is reduced as compared to the case of the rectangular-shaped projecting portion 1a in embodiment 1. Meanwhile, the current confinement effect is determined by the width W₃ of the top of the trapezoidal-shaped projecting portion 1b and therefore is equivalent to that of the optical semiconductor device 100 according to embodiment 1.

As described above, in the optical semiconductor device 110 according to embodiment 2, the sectional shape along the stripe width direction of the projecting portion 1b of the first-conductivity-type semiconductor substrate 1 is a trapezoidal shape, whereby an effect that the element resistance can be reduced is also provided in addition to the effects provided by the optical semiconductor device according to embodiment 1.

### Embodiment 3

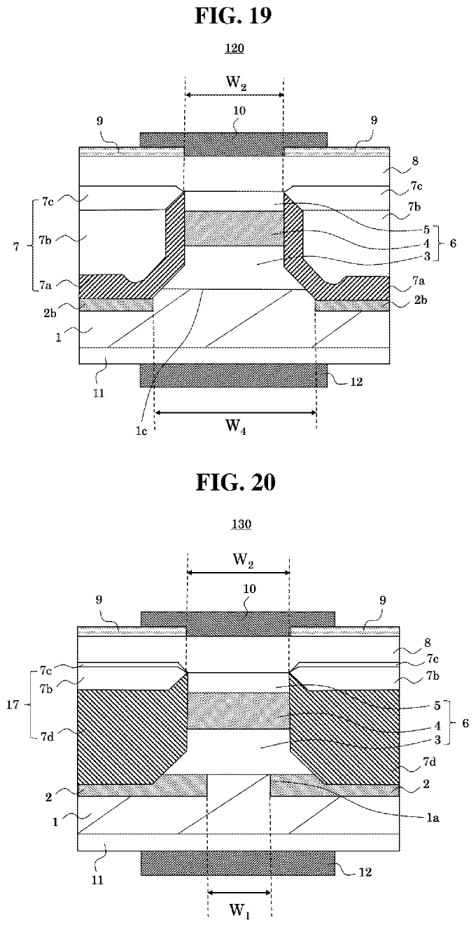

FIG. 19 shows a sectional view of an optical semiconductor device 120 according to embodiment 3. As a structural difference from the optical semiconductor device 100 according to embodiment 1, the optical semiconductor device 120 according to embodiment 3 is configured such that a width W₄ of a projecting portion 1c in the stripe width direction is the same as or substantially the same as the width between contact parts of the bottom portions 6c of the mesa structure 6, i.e., the width between the ends of the bottom portions 6c of the mesa structure 6.

In the optical semiconductor device 120 according to embodiment 3, since the width W₄ of the projecting portion 1c coincides with the width between the ends of the bottom portions 6c of the mesa structure 6, the current confinement effect by second-conductivity-type intermediate layers 2b does not occur. The width of the top of the projecting portion 1c is smaller than the width W₄ of the projecting portion 1c. This is because corners of the top of the projecting portion 1c are removed when the mesa structure 6 is formed through dry etching. Therefore, the width W₄ of the projecting portion 1c refers to the width of a part of the projecting portion 1c other than the part whose corners are removed so as to form parts of the slope surfaces 6b of the mesa structure 6.

In the optical semiconductor device 100 according to embodiment 1, if the layer thickness of the projecting portion 1a is increased in order to more effectively prevent occurrence of leak current due to production of a part having a relatively small layer thickness due to the transition plane 7f formed at the second-conductivity-type first buried layer 7a, since the width W₁ of the projecting portion 1a in the stripe width direction is smaller than the mesa width W₂ of the mesa structure 6, the distance that current flows in a region having a narrower sectional area increases relative to current flowing in the mesa structure 6, so that the element resistance of the optical semiconductor device 100 increases to a certain extent.

On the other hand, in the optical semiconductor device 120 according to embodiment 3, since the width W₄ of the projecting portion 1c is greater than the mesa width W₂ of the mesa structure 6, the element resistance becomes small. Therefore, it becomes possible to design the layer thicknesses of the second-conductivity-type intermediate layers 2b so as to more effectively prevent leak current from the second-conductivity-type first buried layers 7a, while reducing the element resistance. That is, an effect of increasing the degree of freedom in designing of the layer thicknesses of the second-conductivity-type intermediate layers 2b, is provided.

The optical semiconductor device 100 according to embodiment 1 needs to be configured such that the center in the stripe width direction of the mesa structure 6 coincides with the center in the stripe width direction of the projecting portion 1a. Then, if these centers are shifted from each other, the current distribution in the stripe width direction in the active layer 4 might be biased with respect to the center, and the bias of the current distribution might adversely affect the element property. Therefore, in order to produce the optical semiconductor device 100 according to embodiment 1 with a high yield, production technology having high accuracy to a certain extent is needed.

On the other hand, in the optical semiconductor device 120 according to embodiment 3, the width W₄ of the projecting portion 1c is greater than the mesa width W₂ of the mesa structure 6 as described above. Therefore, even if the center of the projecting portion 1c is shifted to a certain extent relative to the center of the bottom portions 6c of the mesa structure 6, the current distribution is not influenced, so that the element property is not adversely affected. Thus, an effect that the optical semiconductor device can be more easily produced is provided.

As described above, in the optical semiconductor device 120 according to embodiment 3, since the width W₄ of the projecting portion 1c is set to be the same as the width between the ends of the bottom portions 6c of the mesa structure 6, the width W₄ of the projecting portion 1c is greater than the mesa width W₂, and the degree of freedom in designing of the layer thicknesses of the second-conductivity-type intermediate layers 2b is increased. Therefore, while the leak current is small, the element resistance becomes smaller and production technology having high accuracy is not needed, thus providing an effect of obtaining the optical semiconductor device that can operate with high efficiency and at high speed and that can be more easily produced.

### Embodiment 4

FIG. 20 shows a sectional view of an optical semiconductor device 130 according to embodiment 4. As a structural difference from the optical semiconductor device 100 according to embodiment 1, the optical semiconductor device 130 according to embodiment 4 is configured such that, of buried layers 17 formed on both sides of the mesa structure 6, first buried layers 7d are formed of high-resistance semiconductor layers, instead of a second-conductivity-type crystal material, e.g., a conductive crystal material such as p-type InP.

An example of the high-resistance semiconductor layer forming the first buried layer 7d is a crystal layer doped with impurities such as iron. A specific example thereof is a semi-insulating InP material doped with iron.

By applying the first buried layer 7d which is a high-resistance semiconductor layer as the first layer of the buried layer 17, an effect that leak current caused at the buried layer 17 is further reduced is provided. In addition, since the leak current is further reduced, the element capacitance can also be reduced. Not only the first buried layer 7d but also the intermediate layer 2 may be formed of a high-resistance semiconductor layer.

As described above, in the optical semiconductor device 130 according to embodiment 4, the first buried layer 7d which is a high-resistance semiconductor layer is applied as the first layer of the buried layer 17, whereby the leak current and the element capacitance can be further reduced, thus providing an effect of obtaining the optical semiconductor device that operates with high efficiency and at high speed.

### Embodiment 5

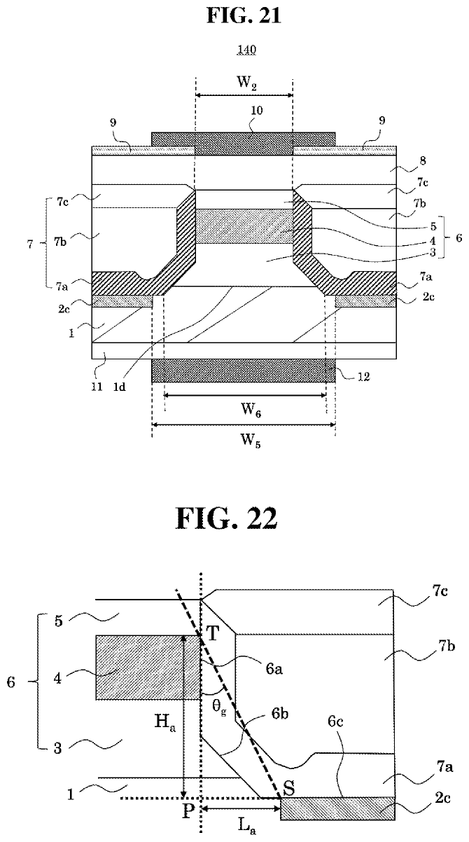

FIG. 21 shows a sectional view of an optical semiconductor device 140 according to embodiment 5. As a structural difference from the optical semiconductor device 120 according to embodiment 3, the optical semiconductor device 140 according to embodiment 5 is configured such that a width W₅ between the ends, of second-conductivity-type intermediate layers 2c provided on both sides of the mesa structure 6, that contact with a projecting portion 1d of the first-conductivity-type semiconductor substrate 1 is greater than a width W₆ between contact parts of the bottom portions 6c of the mesa structure 6, i.e., the width W₆ between the ends of the bottom portions 6c of the mesa structure 6.

In the optical semiconductor device 140 according to embodiment 5, as described above, the width W₅ between the ends, of the second-conductivity-type intermediate layers 2c provided on both sides of the mesa structure 6, that contact with the side surfaces of the projecting portion 1d of the first-conductivity-type semiconductor substrate 1 is set in advance to be greater than the width W₆ between the ends of the bottom portions 6c of the mesa structure 6.

With this configuration adopted, even if production error occurs when the optical semiconductor device is produced, and the center of the width W₅ corresponding to the opening width of the second-conductivity-type intermediate layers 2c is shifted to a certain extent relative to the center of the mesa structure 6 due to the production error, the element property is not adversely affected, thus providing an effect that the optical semiconductor device can be more easily produced.

In the optical semiconductor device 140 according to embodiment 5, the ends, of the second-conductivity-type intermediate layers 2c, that contact with the projecting portion 1d of the first-conductivity-type semiconductor substrate 1 are located more distant from the center of the mesa structure 6 than the parts where the slope surfaces 6b and the bottom portions 6c of the mesa structure 6 contact with each other. Therefore, when the layer thicknesses of the second-conductivity-type intermediate layers 2c are changed, the influence on the element resistance of the optical semiconductor device 140 is very small. Thus, the degree of freedom in designing of the layer thicknesses of the second-conductivity-type intermediate layers 2c is further increased.

Thus, in the optical semiconductor device 140 according to embodiment 5, with the above structure adopted, the degree of freedom in designing of the layer thicknesses of the second-conductivity-type intermediate layers 2c is further increased, so that the element resistance becomes smaller and the leak current and the element capacitance are reduced, thus providing an effect of obtaining the optical semiconductor device that can operate with high efficiency and at high speed and that can be more easily produced because production technology having high accuracy is not needed.

### Embodiment 6

FIG. 22 shows an enlarged view of a major part of an optical semiconductor device according to embodiment 6. The optical semiconductor device according to embodiment 6 has the same layer configuration as the optical semiconductor device 140 according to embodiment 5, but has the following feature.

In FIG. 22, P is defined as a part at which a plane formed by extending, toward the mesa structure 6 side, a plane where the second-conductivity-type intermediate layer 2c contacts with the second-conductivity-type first buried layer 7a, and a plane formed by extending the side surface 6a of the mesa structure 6 toward the first-conductivity-type semiconductor substrate 1 side, cross each other. In addition, S is defined as a corner of a plane where the end of the second-conductivity-type intermediate layer 2c contacts with the second-conductivity-type first buried layer 7a, and T is defined as a corner, on the second-conductivity-type second cladding layer 5 side, where the active layer 4 contacts with the side surface 6a of the mesa structure 6.

Further, Lₐ is defined as the length between P and S, i.e., the distance from the end of the second-conductivity-type intermediate layer 2c to the plane extended from the side surface 6a of the mesa structure 6, Hₐ is defined as the length between T and P, i.e., the height (distance) from the plane where the second-conductivity-type intermediate layer 2c contacts with the second-conductivity-type first buried layer 7a to the upper end of the active layer 4, i.e., the plane where the active layer 4 contacts with the second-conductivity-type second cladding layer 5, and θ_{g} is defined as an angle formed by a segment TS and a segment TP shown in FIG. 22. Then, the angle θ_{g} is represented by the following Expression (1).

Lₐ=Hₐ·tan(θ_{g}) (1)

In the optical semiconductor device according to embodiment 6, the distance Lₐ and the height (distance) Hₐ are set such that the angle θ_{g} is not less than 35.3°. The reason for this setting of the angle θ_{g} is as follows. From the corner S of the plane where the end of the second-conductivity-type intermediate layer 2c contacts with the second-conductivity-type first buried layer 7a, a dislocation might extend in each epitaxially growing layer along the crystal plane. Even in this case, if the angle θ_{g} is not less than 35.3°, the dislocation starting from the corner S extends toward a higher position than T which is the position of the upper end of the active layer 4. Thus, the dislocation is not produced inside the active layer 4.

If a dislocation is produced inside the active layer 4, reliability of the optical semiconductor device is significantly lost. However, in the optical semiconductor device according to embodiment 6, the distance Lₐ and the height (distance) Hₐ are set in advance such that the angle θ_{g} is not less than 35.3°, whereby a reliable optical semiconductor device can be obtained.

When θ_{g} is set to 35.3°, tan (θ_{g}) is tan (35.3°). Since tan (35.3°) is 0.708, the distance Lₐ and the height (distance) Hₐ are set in advance so as to satisfy the following Expression (2).

Lₐ≥0.708Hₐ (2)

The above description is summarized as follows: the distance Lₐ from the part at which the plane along the side surface 6a of the mesa structure 6 and the plane where the second-conductivity-type intermediate layer 2c contacts with the second-conductivity-type first buried layer 7a cross each other, to the end on the side where the second-conductivity-type intermediate layer 2c contacts with the second-conductivity-type first buried layer 7a, is not less than a distance obtained by multiplying the height (distance) Hₐ from the plane where the second-conductivity-type intermediate layer 2c contacts with the second-conductivity-type first buried layer 7a to the upper end of the active layer 4 by 0.708.

Thus, in the optical semiconductor device according to embodiment 6, with the above structure adopted, an effect of obtaining a more reliable optical semiconductor device is provided in addition to the effects provided by the optical semiconductor device 140 according to embodiment 5.

The optical semiconductor device according to each embodiment 1 to 6 described above is, for example, an InP-based long-wavelength semiconductor laser for a wavelength of 1.3 to 1.55 μm used as a light source for optical communication. By using such a semiconductor laser, it becomes possible to reduce loss in a silica optical fiber.

In embodiments 1 to 6, as a specific example of the optical semiconductor device, a semiconductor laser has been described. This semiconductor laser includes a modulator integrated semiconductor laser (electro-absorption modulator integrated laser diode; EML). The optical semiconductor device according to each embodiment 1 to 6 is applicable also to an electro-absorption (EA) part of the EML. The optical semiconductor device according to each embodiment 1 to 6 may be applied to all various optical semiconductor devices.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 semiconductor substrate
1a, 1b, 1c, 1d projecting portion
2, 2a, 2b, 2c intermediate layer
3 first cladding layer
4 active layer
5 second cladding layer
6 mesa structure
6a side surface
6b slope surface
6c, 6d bottom portion
7, 17 buried layer
7a, 7d first buried layer
7b second buried layer
7c third buried layer
7f transition plane
8 contact layer
9 surface protection film
10 first electrode
11 second electrode
12 metal plating film
20, 22 mask
20a, 22a SiO₂ film
21, 23 photoresist mask
23a photoresist film
27a side surface portion
27b slope portion
27c, 27d flat portion
100, 110, 120, 130, 140, 200 optical semiconductor device

1. An optical semiconductor device comprising:
a first-conductivity-type semiconductor substrate having a projecting portion;
second-conductivity-type intermediate layers formed on both sides of the projecting portion above the semiconductor substrate;
a stripe-shaped mesa structure formed of a first-conductivity-type first cladding layer, an active layer, and a second-conductivity-type second cladding layer, which are laminated above a surface including a top of the projecting portion so as to be centered at the projecting portion;
buried layers formed on both sides of the mesa structure, to block current; and
a second-conductivity-type contact layer formed at surfaces of the mesa structure and the buried layers, wherein
a width between ends of the intermediate layers that contact with the projecting portion in a stripe width direction is greater than a width between ends of bottom portions of the mesa structure in the stripe width direction,
the mesa structure has, on each of both sides thereof, a side surface along a direction perpendicular to a surface of the semiconductor substrate, a bottom portion on the intermediate layer side, and a slope surface connecting the side surface and the bottom portion,
the buried layers are each formed of a second-conductivity-type or high-resistance first buried layer, a first-conductivity-type second buried layer, and a second-conductivity-type third buried layer, which are sequentially laminated on both sides of the mesa structure, and
a distance from a part at which a plane along the side surface of the mesa structure and a plane where the intermediate layer contacts with the first buried layer cross each other, to an end on a side where the intermediate layer contacts with the first buried layer, is not less than a distance obtained by multiplying a distance from the plane where the intermediate layer contacts with the first buried layer to an upper end of the active layer by 0.708.

2. The optical semiconductor device according to claim 1, further comprising:
a surface protection film formed above the second-conductivity-type contact layer and having an opening;
a first electrode contacting with a surface of the second-conductivity-type contact layer via the opening of the surface protection film; and
a second electrode formed on a back surface side of the first-conductivity-type semiconductor substrate.

3.-8. (canceled)

9. The optical semiconductor device according to claim 1, wherein
the first buried layer is formed of a side surface portion covering the side surface of the mesa structure, a slope portion covering the slope surface of the mesa structure, and a flat portion covering a surface of the intermediate layer.

10. The optical semiconductor device according to claim 2, wherein
a layer thickness of the flat portion in the first buried layer is not less than two times a layer thickness of the side surface portion.

11. (canceled)

12. An optical semiconductor device production method comprising the steps of:
forming a projecting portion on a first-conductivity-type semiconductor substrate through etching;
epitaxially growing intermediate layers on both sides of the projecting portion;
sequentially epitaxially growing a first-conductivity-type first cladding layer, an active layer, and a second-conductivity-type second cladding layer at surfaces of the projecting portion and the intermediate layers;
forming, through etching, a stripe-shaped mesa structure whose center coincides with a center of the projecting portion and which is formed of the first cladding layer, the active layer, and the second cladding layer;
epitaxially growing buried layers for blocking current, on both sides of the mesa structure; and
epitaxially growing a second-conductivity-type contact layer at surfaces of the mesa structure and the buried layers, wherein
a width between ends of the intermediate layers that contact with the projecting portion in a stripe width direction is formed to be greater than a width between ends of bottom portions of the mesa structure in the stripe width direction,
the mesa structure is formed to have, on each of both sides thereof, a side surface along a direction perpendicular to a surface of the semiconductor substrate, a bottom portion on the intermediate layer side, and a slope surface connecting the side surface and the bottom portion,
the buried layers are each formed by three layers that are a second-conductivity-type or high-resistance first buried layer, a first-conductivity-type second buried layer, and a second-conductivity-type third buried layer, which are sequentially laminated on both sides of the mesa structure, and
a distance from a part at which a plane along the side surface of the mesa structure and a plane where the intermediate layer contacts with the first buried layer cross each other, to an end on a side where the intermediate layer contacts with the first buried layer, is not less than a distance obtained by multiplying a distance from the plane where the intermediate layer contacts with the first buried layer to an upper end of the active layer by 0.708.

13. The optical semiconductor device production method according to claim 12, wherein
etching is performed so that a sectional shape along a stripe width direction of the projecting portion becomes a rectangular shape or a trapezoidal shape.

14.-18. (canceled)
